(19) United States
(12) Patent Application Publication
(10) Pub. No.: US 2025/0079286 A1
(43) Pub. Date: Mar. 6, 2025

(54) CIRCUIT BOARD AND SEMICONDUCTOR PACKAGE COMPRISING SAME

(71) Applicant: LG INNOTEK CO., LTD., Seoul (KR)

(72) Inventors: Jung Hoon PARK, Seoul (KR); Nam Heon KIM, Seoul (KR)

(73) Assignee: LG INNOTEK CO., LTD., Seoul (KR)

(21) Appl. No.: 18/726,754

(22) PCT Filed: Jan. 3, 2023
(86) PCT No.: PCT/KR2023/000092

§ 371 Date: Jul. 3, 2024

(30) Foreign Application Priority Data
Jan. 3, 2022 (KR) 10-2022-0000595

(51) Int. Cl. H01L 23/498; H05K 1/02

(52) U.S. Cl. CPC H01L 23/49838; H01L 23/49822; H05K 1/0284

(57) ABSTRACT

A circuit board according to an embodiment includes an insulating layer having a concave portion on an upper surface thereof; a first circuit pattern layer disposed in the concave portion of the insulating layer; and a protective layer disposed on the first circuit pattern layer; wherein the first circuit pattern layer includes: a first metal layer, and a second metal layer disposed on the first metal layer to fill a stepped portion between an upper surface of the first metal layer and an upper surface of the insulating layer, and the protective layer includes an opening overlapping the second metal layer in a vertical direction.

### TECHNICAL FIELD

An embodiment relates to a circuit board and a semiconductor comprising the same.

### BACKGROUND ART

A line width of a circuit has been miniaturized as miniaturization, weight reduction, and integration of an electronic component are accelerated. In particular, as a design rule of a semiconductor chip is integrated on a nanometer scale, a circuit line width of a package substrate or a printed circuit board on which the semiconductor chip is mounted has been miniaturized to several micrometers or less.

Various methods have been proposed in order to increase the degree of circuit integration of the printed circuit board, that is, to reduce the circuit line width. For the purpose of preventing loss of the circuit line width in an etching step for forming a pattern after copper plating, a semi-additive process (SAP) method and a modified semi-additive process (MSAP) have been proposed.

Then, an embedded trace substrate (hereinafter referred to as “ETS”) method for embedding a copper foil in an insulating layer in order to implement a fine circuit pattern has been used in the industry. The ETS method is manufactured by embedding a copper foil circuit in an insulating layer instead of forming the copper foil circuit on a surface of the insulating layer, and thus there is no circuit loss due to etching and it is advantageous for miniaturizing the circuit pitch.

Meanwhile, recently, efforts have been made to develop an improved 5G (5th generation) communication system or a pre-5G communication system in order to meet a demand for wireless data traffic. Here, the 5G communication system uses ultra-high frequency (mmWave) bands (sub 6 GHz, 28 GHz, 38 GHz, or higher frequencies) to achieve high data transfer rates.

In addition, integration technologies such as beamforming, massive multi-input multi-output (massive MIMO), and array antennas have been developed in the 5G communication system in order to reduce a path loss of radio waves and increase a transmission distance of radio waves in the ultra-high frequency band. Antenna systems are relatively large given that they can consist of hundreds of active antennas of wavelengths in these frequency bands.

Since such an antenna and AP module are patterned or mounted on the printed circuit board, low loss on the printed circuit board is very important. This means that several substrates constituting the active antenna system, that is, an antenna substrate, an antenna power feeding substrate, a transceiver substrate, and a baseband substrate, should be integrated into one compact unit.

As described above, miniaturization of the circuit pattern is more important because various substrates must be integrated into one small device for the circuit board applied to the 5G communication system. To this end, the circuit pattern layer included in the circuit board has an ETS structure.

However, in a circuit board including a circuit pattern layer having a conventional ETS structure, there is a problem in physical or electrical reliability of a buried pattern disposed on an outermost side.

Accordingly, there is a demand for a circuit board including a circuit pattern layer having a novel ETS structure.

### DISCLOSURE

### Technical Problem

An embodiment provides a circuit board having a novel structure and a semiconductor package having the same.

In addition, the embodiment provides a circuit board capable of improving reliability of a circuit pattern layer disposed on an outermost side and a semiconductor package having the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment includes an insulating layer having a concave portion on an upper surface thereof; a first circuit pattern layer disposed in the concave portion of the insulating layer; and a protective layer disposed on the first circuit pattern layer; wherein the first circuit pattern layer includes: a first metal layer; and a second metal layer disposed on the first metal layer to fill a stepped portion between an upper surface of the first metal layer and an upper surface of the insulating layer, and the protective layer includes an opening overlapping the second metal layer in a vertical direction.

In addition, a width of the opening of the protective layer is smaller than a width of the second metal layer; and at least a portion of an upper surface of the second metal layer is covered with the protective layer.

In addition, the first metal layer and the second metal layer include different metal materials.

In addition, side surfaces of the first and second metal layers are disposed on the same plane as an inner wall of the concave portion.

In addition, the upper surface of the first metal layer is positioned lower than the upper surface of the insulating layer, and wherein an upper surface of the second metal layer is positioned on the same plane as the upper surface of the insulating layer.

In addition, the first metal layer includes copper, and the second metal layer includes a metal material other than copper.

In addition, the second metal layer is provided with a plurality of layers including different metal materials.

In addition, the second metal layer includes: a first layer disposed on the first metal layer; a second layer disposed on the first layer; and a third layer disposed on the second layer.

In addition, the first layer of the second metal layer includes nickel, the second layer of the second metal layer includes palladium, and the third layer of the second metal layer includes gold.

In addition, the insulating layer is provided with a plurality of layers, and the concave portion is provided on an upper surface of an insulating layer disposed on an uppermost side among the plurality of layers.

In addition, a width of the first metal layer is same as a width of the second metal layer.

In addition, a side surface of the first metal layer and a side surface of the second metal layer are entirely covered with the insulating layer.

In addition, a thickness of the first layer of the second metal layer has a range of 0.1 μm to 1.0 μm, a thickness of the second layer of the second metal layer has a range of 0.01 μm to 0.08 μm, and a thickness of the third layer of the second metal layer has a range of 0.01 μm to 0.08 μm.

In addition, a thickness of the first layer of the second metal layer has a range of 3.0 μm to 7.0 μm, a thickness of the second layer of the second metal layer has a range of 0.01 μm to 0.08 μm, and a thickness of the third layer of the second metal layer has a range of 0.01 μm to 0.08 μm.

In addition, a thickness of the third layer of the second metal layer ranges from 0.95 times to 1.05 times the thickness of the second layer of the second metal layer, and a thickness of the first layer of the second metal layer ranges from 1.25 times to 100 times a thickness of any one of a thickness of the second layer of the second metal layer and a thickness of the third layer of the second metal layer.

In addition, a thickness of the third layer of the second metal layer ranges from 0.95 times to 1.05 times a thickness of the second layer of the second metal layer, and a thickness of the first layer of the second metal layer ranges from 35 times to 700 times a thickness of any one of a thickness of the second layer of the second metal layer and a thickness of the third layer of the second metal layer.

In addition, the circuit board further includes a second circuit pattern layer disposed under a lower surface of the insulating layer; and wherein a number of metal layers of the second circuit pattern layer is smaller than a number of metal layers of the first circuit pattern layer.

In addition, the first circuit pattern layer includes a pad and a trace, wherein each of the pad and the trace includes the first metal layer, the first layer of the second metal layer, the second layer of the second metal layer, and the third layer of the second metal layer.

Meanwhile, a semiconductor package according to an embodiment includes an insulating layer having a concave portion on an upper surface thereof; a first circuit pattern layer disposed in the concave portion of the insulating layer; a protective layer disposed on the first circuit pattern layer and including an opening overlapping the first circuit pattern layer in a vertical direction; a connection portion disposed in the opening of the protective layer; and a chip disposed on the connection portion; wherein the first circuit pattern layer, a first metal layer; and a second metal layer disposed on the first metal layer to fill a stepped portion between an upper surface of the first metal layer and an upper surface of the insulating layer, and an upper surface of the second metal layer is positioned on the same plane as an upper surface of the insulating layer.

In addition, the chip includes first and second chips spaced apart in a vertical or horizontal direction, wherein the first chip includes a central processor (CPU), and the second chip includes a graphics processor (GPU).

### Advantageous Effects

A circuit board of the embodiment includes a circuit pattern layer having an ETS structure. For example, the circuit board of the embodiment includes a first circuit pattern layer disposed on an upper surface of an insulating layer. The first circuit pattern layer means a circuit pattern layer disposed on an outermost side of the circuit board. The first circuit pattern layer includes a plurality of metal layers. The first circuit pattern layer includes a first metal layer and a second metal layer. The first metal layer may be a barrier layer that prevents the second metal layer from being etched in a process of removing a seed layer used to form the first circuit pattern layer. Accordingly, the embodiment can prevent the second metal layer from being etched when the seed layer is etched. Accordingly, the embodiment can remove a step provided between an upper surface of the first circuit pattern layer and the insulating layer, thereby improving physical and electrical reliability. Specifically, the embodiment may allow an upper surface of the first circuit pattern layer and an upper surface of the insulating layer to be positioned on the same plane.

Meanwhile, the first metal layer according to the embodiment may have a multi-layer structure. The first metal layer may include a first-first metal layer, a first-second metal layer, and a first-third metal layer. The first-first metal layer may refer to a metal layer disposed at an outermost part of the first circuit pattern layer. For example, the first metal layer may include a gold metal layer, a palladium metal layer, and a nickel metal layer in order from an upper part, and the second metal layer may include a copper metal layer. In this case, an upper surface of the first-first metal layer may improve solder bonding and wire bonding properties while preventing etching and oxidation of the first circuit pattern layer. The first-second metal layer enables a solder reflow process at a high temperature, thereby improving of the second metal layer. As described above, the first metal layer of the embodiment may have a three-layer structure, and accordingly, it can improve the physical and electrical reliability of the first circuit pattern layer.

### DESCRIPTION OF DRAWINGS

FIG. 1 is a view showing a circuit board according to a comparative example.

FIGS. 2 and 3 are views showing a circuit board according to an embodiment.

FIG. 4 is a plan view of a state in which some components are removed from FIGS. 2 and 3.

FIG. 5 is a view showing a semiconductor package according to an embodiment.

FIGS. 6 to 18 are views showing a manufacturing method of the circuit board shown in FIG. 2 in order of process.

### BEST MODE

Hereinafter, the embodiment disclosed in the present specification will be described in detail with reference to the accompanying drawings, but the same or similar components are designated by the same reference numerals regardless of drawing numbers, and repeated description thereof will be omitted. The component suffixes “module” and “part” used in the following description are given or mixed together only considering the ease of creating the specification, and have no meanings or roles that are distinguished from each other by themselves. In addition, in describing the embodiments disclosed in the present specification, when it is determined that detailed descriptions of a related well-known art unnecessarily obscure gist of the embodiments disclosed in the present specification, the detailed description thereof will be omitted. Further, the accompanying drawings are merely for facilitating understanding of the embodiments disclosed in the present specification, the technological scope disclosed in the present specification is not limited by the accompanying drawings, and it should be understood as including all modifications, equivalents and alternatives that fall within the spirit and scope of the present invention.

It will be understood that, although the terms “first,” “second,” etc. may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, it will be understood that there are no intervening elements present.

As used herein, a singular expression includes a plural expression, unless the context clearly indicates otherwise.

It will be understood that the terms “comprise”, “include”, or “have” specify the presence of stated features, integers, steps, operations, elements, components and/or groups thereof disclosed in the present specification, but do not preclude the possibility of the presence or addition of one or more other features, integers, steps, operations, elements, components, and/or groups thereof.

Hereinafter, embodiments of the present invention will be described in detail with reference to accompanying drawings.

### Comparative Example (Prior Art)

Before describing the embodiment, a comparative example compared to the present embodiment will be described.

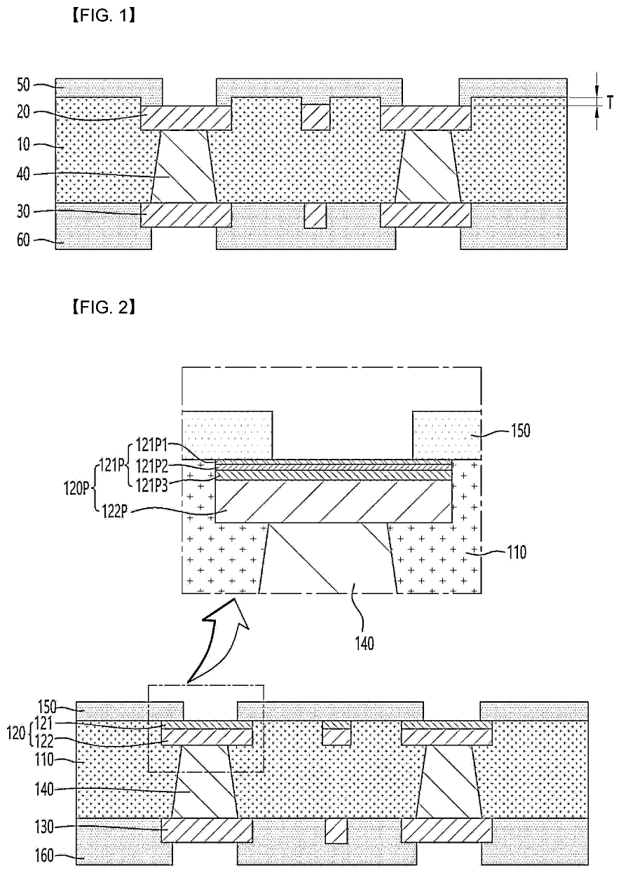

FIG. 1 is a view showing a circuit board according to a comparative example.

Referring to FIG. 1, the circuit board of the comparative example may have an ETS structure. For example, the circuit board includes an insulating layer 10, a first circuit pattern layer 20, a second circuit pattern layer 30, a through electrode 40, a first protective layer 50, and a second protective layer 60.

The first circuit pattern layer 20 and the second circuit pattern layer 30 are respectively disposed on upper and lower surfaces of the insulating layer 10.

That is, the first circuit pattern layer 20 is disposed on the upper surface of the insulating layer 10. And, the second circuit pattern layer 30 is disposed under the lower surface of the insulating layer 10.

In this case, an upper surface of the first circuit pattern layer 20 is positioned lower than the upper surface of the insulating layer 10. This is because a portion of the first circuit pattern layer 20 is also removed during an etching process of a seed layer (not shown) used in a process of forming the first circuit pattern layer 20.

For example, the upper surface of the first circuit pattern layer 20 may be positioned on the same plane as the upper surface of the insulating layer 10 before etching the seed layer.

In addition, the first circuit pattern layer 20 is removed together with the seed layer after etching the seed layer. Accordingly, a step (T) may exist between the upper surface of the first circuit pattern layer 20 and the upper surface of the insulating layer 10.

The first circuit pattern layer 20 may be used as a mounting pad on which a chip is mounted.

In this case, when a step (T) exists between the upper surface of the first circuit pattern layer 20 and the upper surface of the insulating layer 10, a height of a solder ball (not shown) for mounting a chip is lowered by the stop (T). Accordingly, the comparative example has a problem in that a thickness of the solder ball must be increased by the step (T). In addition, when the thickness of the solder ball increases, manufacturing cost increases. In addition, when the thickness of the solder ball increases, a strength of the solder ball is also weakened, and accordingly, the solder ball collapses during a chip mounting process.

Meanwhile, the first protective layer 50 is disposed on the upper surface of the insulating layer 10. In this case, the first protective layer 50 includes a first overlapping region overlapping the upper surface of the insulating layer 10 and a second overlapping region overlapping the upper surface of the first circuit pattern layer 20.

In this case, a step may be formed on an upper surface of the first protective layer 50 of the comparative example by the step (T) provided on the upper surface of the insulating layer 10 and the upper surface of the first circuit pattern layer 20. For example, the upper surface of the first overlapping region overlapping the upper surface of the insulating layer 10 among the upper surface of the first protective layer 50 may be positioned higher than the upper surface of the second overlapping region overlapping the upper surface of the first circuit pattern layer 20. Accordingly, the upper surface of the first protective layer 50 of the comparative example has a wavy shape, and there is a problem of deteriorating design reliability.

On the other hand, the comparative example in FIG. 1 is shown as having a one-layer structure based on a number of layers of the insulating layer 10, but is not limited thereto. For example, the circuit board may have two or more layers, four or more layers, or eight or more layers based on a number of layers of the insulating layer 10.

For example, the number of insulating layers of the circuit board may have 8 to 10 layers to be applied to an AP module with high integration and high specifications. In this case, the first circuit pattern layer 20, which is a fine pattern, is first formed during the ETS process. Then, a lamination process of the insulating layer and the circuit pattern layer having 8 to 10 layers is performed in a state where the first circuit pattern layer 20 is formed. However, damage may be applied to the first circuit pattern layer 20 of the comparative example due to thermal stress generated in the lamination process, and thus the first circuit pattern layer 20 may be damaged.

Accordingly, the embodiment allows the first circuit pattern layer to have a multi-layered structure in a process of forming the first circuit pattern layer, thereby improving physical and electrical reliability of the first circuit pattern layer. Specifically, in the embodiment, a barrier layer is preferentially formed before forming an electrolytic plating layer using the seed layer in the process of forming the first circuit pattern layer. In addition, the embodiment enables the first circuit pattern layer to be stably protected by using the barrier layer. For example, the embodiment solves the problem that the first circuit pattern layer is removed by the barrier layer in the etching process of the seed layer. For example, the embodiment minimizes thermal stress applied to the first circuit pattern layer by using the barrier layer in a process of manufacturing a circuit board having a multilayer structure.

Hereinafter, a circuit board according to an embodiment and a semiconductor package including the circuit board will be described in detail.

### Electronic Device

Before describing the embodiment, an electronic device including the semiconductor package of the embodiment will be briefly described.

In this case, the electronic device includes a main board (not shown). The main board may be physically and/or electrically connected to various components. For example, the main board may be connected to the semiconductor package of the embodiment. Various chips may be mounted on the semiconductor package. Broadly, memory chips such as volatile memory (eg DRAM), non-volatile memory (eg ROM), flash memory, and the like, an application processor chip such as a central processor (eg, CPU), a graphics processor (eg, GPU), a digital signal processor, an encryption processor, a microprocessor, and a microcontroller, and a logic chip such as an analog-to-digital converter or an application-specific IC (ASIC) may be mounted on the semiconductor package.

Further, the embodiment provides a semiconductor package capable of mounting at least two different types of chips on one substrate while reducing the thickness of the semiconductor package connected to the main board of the electronic device.

In this case, the electronic device may be a smart phone, a personal digital assistant, a digital video camera, a digital still camera, a network system, computer, a monitor, a tablet, a laptop, a netbook, a television, a video game, a smart watch, an automotive, or the like. However, the embodiment is not limited thereto, and in addition to these, any other electronic device for processing data may be included.

Hereinafter, a circuit board according to an embodiment and a package substrate including the circuit board will be described.

### Circuit Board

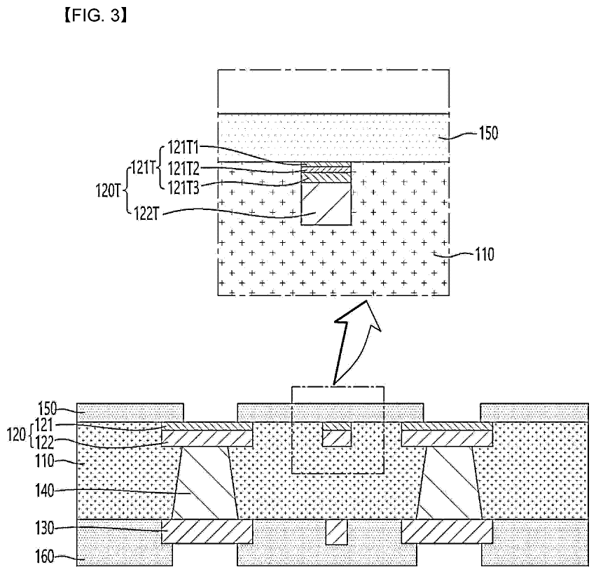

FIGS. 2 and 3 are views showing a circuit board according to an embodiment, and FIG. 4 is a plan view of FIGS. 2 and 3 in a state in which some components are removed. Specifically, FIG. 2 includes an enlarged view of a pad of a first circuit pattern layer of a circuit board, and FIG. 3 includes an enlarged view of a trace of a first circuit pattern layer of a circuit board. In addition, FIG. 4 is a plan view of FIG. 2 or 3 in a state in which a first protective layer is removed. In addition, FIGS. 2 and 3 are cross-sectional views taken along a A-A′ direction in the plan view of FIG. 4.

Hereinafter, a circuit board according to an embodiment will be described in detail with reference to FIGS. 2 to 4.

The circuit board of the embodiment provides a mounting space in which at least one chip can be mounted. The number of chips mounted on the circuit board of the embodiment may be one, alternatively two, and alternatively three or more. For example, one processor chip may be mounted on a circuit board. Alternatively, at least two processor chips having different functions may be mounted on the circuit board. Alternatively, one memory chip and one processor chip may be mounted on the circuit board. Alternatively, at least two processor chips having different functions and at least one memory chip may be mounted on the circuit board.

The circuit board includes an insulating layer 110. The insulating layer 110 may have a one-layer structure. However, the embodiment is not limited thereto, and the insulating layer 110 may have a multilayer structure of two or more layers.

However, hereinafter, for convenience of description, the circuit board will be described as having a one-layer structure based on the number of layers of the insulating layer 110.

The insulating layer 110 may include a prepreg (PPG). The prepreg may be formed by impregnating a fiber layer in the form of a fabric sheet, such as a glass fabric woven with glass yarn, with an epoxy resin, and then performing thermal compression. However, the embodiment is not limited thereto, and the prepreg constituting the insulating layer 110 may include a fiber layer in the form of a fabric sheet woven with carbon fiber threads.

The insulating layer 110 may include a resin and reinforcing fibers disposed in the resin. The resin may be an epoxy resin, but is not limited thereto. The resin is not particularly limited to an epoxy resin, and for example, one or more epoxy groups may be included in the molecule, two or more epoxy groups may be included, and, alternatively, four or more epoxy groups may be included. In addition, the resin of the insulating layer 110 may include a naphthalene group, and may be, for example, an aromatic amine type, but is not limited thereto. For example, the resin is bisphenol A type epoxy resin, bisphenol F type epoxy resin, bisphenol S type epoxy resin, phenol novolak type epoxy resin, alkylphenol novolak type epoxy resin, biphenyl type epoxy resin, aralkyl type epoxy resins, dicyclopentadiene type epoxy resins, naphthalene type epoxy resins, naphthol type epoxy resins, epoxy resins of condensates of phenols and aromatic aldehydes having a phenolic hydroxyl group, biphenyl aralkyl type epoxy resins, fluorene type epoxies resins, xanthene-type epoxy resins, triglycidyl isocyanurate, rubber-modified epoxy resins, and phosphorous-type epoxy resins, naphthalene-type epoxy resins, bisphenol A-type epoxy resins, and phenol novolac epoxy resins, cresol novolak epoxy resins, rubber-modified epoxy resins, and phosphorus-based epoxy resins. In addition, the reinforcing fibers may be glass fibers, carbon fibers, aramid fibers (eg, aramid-based organic materials), nylon, silica-based inorganic materials, or titania-based inorganic materials. The reinforcing fiber may be arranged to cross each other in a planar direction within the resin.

Meanwhile, the reinforcing fiber may be provided with a glass fiber, a carbon fiber, an aramid fiber (eg, aramid-based organic material), a nylon, a silica-based inorganic material, or a titania-based inorganic material.

However, the embodiment is not limited thereto, and the insulating layer 110 may include other insulating materials.

For example, the insulating layer 110 may be rigid or flexible. For example, the insulating layer 110 may include glass or plastic. Specifically, the insulating layer 110 may include a chemically tempered/semi-tempered glass, such as soda lime glass, aluminosilicate glass, etc., a tempered or flexible plastic such as polyimide (PI), polyethylene terephthalate (PET), propylene glycol (PPG), polycarbonate (PC), etc., or sapphire. For example, the insulating layer 110 may include an optically isotropic film. As an example, the insulating layer 110 may include cyclic olefin copolymer (COC), cyclic olefin polymer (COP), optically isotropic PC, optically isotropic polymethylmethacrylate (PMMA), or the like. For example, the insulating layer 110 may be formed of a material including an inorganic filler and an insulating resin. For example, the insulating layer 110 may be formed of a resin containing a reinforcing material such as an inorganic filler such as silica or alumina together with a thermosetting resin such as epoxy resin or a thermoplastic resin such as polyimide, specifically, Ajinomoto Build-up Film (ABF), FR-4, Bismaleimide Triazine (BT), Photo Imageable Dielectric Resin (PID), BT, or the like.

The insulating layer 110 may have a thickness ranging from 10 μm to 100 μm. For example, the insulating layer 110 may have a thickness ranging from 15 μm to 80 μm. For example, the insulating layer 110 may have a thickness ranging from 20 μm to 50 μm. When the thickness of the insulating layer 110 is less than 10 μm, a circuit pattern layer included in the circuit board may not be stably protected. When the thickness of the insulating layer 110 exceeds 100 μm, an overall thickness of the circuit board may increase. In addition, when the thickness of the insulating layer 110 exceeds 100 μm, the thickness of a circuit pattern layer or a through electrode increases correspondingly, and thus loss of a signal transmitted through the circuit pattern may increase.

In this case, the thickness of the insulating layer 110 may correspond to a distance in a thickness direction between circuit patterns disposed on different layers. For example, the thickness of the insulating layer 110 may mean a vertical distance between a lower surface of a first circuit pattern layer 120 and an upper surface of a second circuit pattern layer 130.

A circuit pattern layer is disposed on a surface of the insulating layer 110.

For example, a first circuit pattern layer 120 is disposed on an upper surface of the insulating layer 110. In addition, a second circuit pattern layer 130 is disposed under a lower surface of the insulating layer 110.

In this case, when the insulating layer 110 has a multilayer structure, the first circuit pattern layer 120 may refer to a circuit pattern layer disposed on an uppermost side among a plurality of circuit pattern layers disposed on different layers.

In an embodiment, the circuit board may be manufactured using an embedded trace substrate (ETS) method. Accordingly, at least one of a plurality of circuit patterns included in the circuit board may have an ETS structure. Here, having an ETS structure may mean a structure (eg, a buried structure) in which at least a part of a side surface of an outermost circuit pattern layer disposed on an outermost side is covered with an outermost insulating layer.

For example, at least one of the circuit patterns disposed on each layer of the circuit board may have a structure buried in an insulating layer. For example, in the embodiment, a first circuit pattern layer 120 disposed on an upper surface of the insulating layer 110 may have an ETS structure.

Accordingly, the first circuit pattern layer 120 may have a structure buried in the insulating layer 110. For example, an upper surface of the first circuit pattern layer 120 may not vertically overlap an upper surface of the insulating layer 110. For example, at least a portion of a side surface of the circuit pattern layer 120 may overlap the insulating layer 110 in a horizontal direction.

Accordingly, an upper surface of the first circuit pattern layer 120 may be exposed to an upper side of the circuit board in a state of being disposed on the insulating layer 110. In addition, at least a portion of a side surface of the first circuit pattern layer 120 may be covered by the insulating layer 110. Preferably, an entire side surface of the first circuit pattern layer 120 may be covered with the insulating layer 110.

To this end, a concave portion (not shown) may be formed on an upper surface of the insulating layer 110. In addition, the first circuit pattern layer 120 may be disposed in the concave portion of the insulating layer 110. The concave portion is formed on the upper surface of the insulating layer 110 and may be referred to as a recess that is concave toward a lower surface of the insulating layer 110.

Meanwhile, a second circuit pattern layer 130 may have a structure protruding below a lower surface of the insulating layer 110. For example, the second circuit pattern layer 130 may overlap a lower surface of the insulating layer 110 in a vertical direction. For example, a side surface of the second circuit pattern layer 130 may not overlap with the insulating layer 110 in a horizontal direction. Accordingly, a side surface and a lower surface of the second circuit pattern layer 130 may be entirely exposed to a lower side of the circuit board.

An arrangement structure of circuit patterns disposed on each surface of the insulating layer 110 is as follows.

At least part or all of the first circuit pattern layer 120 may have a structure in which the insulating layer 110 is buried. For example, the first circuit pattern layer 120 may be an outermost circuit pattern layer or an uppermost circuit pattern layer disposed on an outermost side of the circuit board. Accordingly, an upper surface of the first circuit pattern layer 120 may not be higher than an upper surface of the insulating layer 110. Preferably, an upper surface of the first circuit pattern layer 120 in the embodiment may be positioned on the same plane as an upper surface of the insulating layer 110. In addition, a lower surface of the first circuit pattern layer 120 may be positioned lower than an upper surface of the insulating layer 110.

The first circuit pattern layer 120 includes a pad 120P and a trace 120T according to their functions. The pad 120P may be a pad on which a chip is mounted or a pad coupled to an external substrate. The trace 120T may be a signal wiring line connecting a plurality of pads 120P. The trace 120T may have a fine pattern. Accordingly, a space between a plurality of traces may range from 2 μm to 10 μm, and a line width of each trace may range from 2 μm to 10 μm.

The second circuit pattern layer 130 may be disposed under a lower surface of the insulating layer 110. The second circuit pattern layer 130 may protrude below a lower surface of the insulating layer 110.

The first circuit pattern layer 120 and the second circuit pattern layer 130 may be formed of at least one metal material selected from gold (Au), silver (Ag), platinum (Pt), titanium (Ti), tin (Sn), copper (Cu), and zinc (Zn). In addition, the first circuit pattern layer 120 and the second circuit pattern layer 130 may be formed of a paste or solder paste including at least one metal material selected from gold (Au), silver (Ag), platinum (Pt), titanium (Ti), tin (Sn), copper (Cu), and zinc (Zn) having excellent bonding power.

Each of the first circuit pattern layer 120 and the second circuit pattern layer 130 may have a thickness T1 ranging from 5 μm to 20 μm. For example, the first circuit pattern layer 120 and the second circuit pattern layer 130 may have a thickness ranging from 6 μm to 17 μm. Each of the first circuit pattern layer 120 and the second circuit pattern layer 130 may have a thickness ranging from 7 μm to 16 μm. When a thickness of each of the first circuit pattern layer 120 and the second circuit pattern layer 130 is less than 5 μm, resistance of the circuit pattern may increase, and thus signal transmission efficiency may decrease. For example, when a thicknesses of each of the first circuit pattern layer 120 and the second circuit pattern layer 130 is less than 5 μm, signal transmission loss may increase. For example, when a thickness of each of the first circuit pattern layer 120 and the second circuit pattern layer 130 exceeds 20 μm, a line width of a circuit patterns increases, and thus an overall volume of the circuit board increases.

The first circuit pattern layer 120 and the second circuit pattern layer 130 may have different layer structures.

For example, a number of metal layers of the first circuit pattern layer 120 may be different from a number of metal layers of the second circuit pattern layer 130. For example, a number of metal layers of the first circuit pattern layer 120 may be greater than a number of metal layers of the second circuit pattern layer 130.

Here, the number of layers of the metal layer may mean a number of layers of metal layers excluding a seed layer.

For example, the number of metal layers of the first circuit pattern layer 120 excluding a seed layer may be greater than the number of metal layers of the second circuit pattern layer 130 excluding the seed layer.

Alternatively, a number of layers of the metal layer may mean a number of layers of the metal layer including a seed layer.

In this case, a seed layer of the first circuit pattern layer 120 is removed by etching in a final stage of the circuit board manufacturing process, and accordingly, a metal layer of the first circuit pattern layer 120 does not include a seed layer. Alternatively, a metal layer of the second circuit pattern layer 130 may include a seed layer.

Accordingly, a number of metal layers of the first circuit pattern layer 120 may be greater than a number of metal layers of the second circuit pattern layer 130 including the seed layer.

The first circuit pattern layer 120 may include a first metal layer 121 and a second metal layer 122.

The first metal layer 121 may be a metal layer disposed adjacent to an upper surface of the insulating layer 110. A second metal layer 122 may be disposed below the first metal layer 121.

The first metal layer 121 may be a barrier layer. The first metal layer 121 may be a surface treatment layer. Specifically, the first metal layer 121 may be a barrier layer to prevent etching of the first circuit pattern layer 120 in a process of removing a seed layer used for electroplating the first circuit pattern layer 120.

Specifically, in the circuit board of the ETS structure of the comparative example, an outermost first circuit pattern layer 20 includes only the second metal layer. Accordingly, the second metal layer in the comparative example is also removed during an etching process of the seed layer. As a result, a step (T) is provided between an upper surface of the first circuit pattern layer 20 and an upper surface of the insulating layer 10 in the comparative example.

In contrast, the embodiment allows the first circuit pattern layer 120 to include at least one metal layer of a different metal material in a process of forming the first circuit pattern layer 120 by electrolytic plating using a seed layer. The metal layer of the different metal material may be a barrier layer, and thus may mean the first metal layer 121.

In addition, the first metal layer 121 may function as an etching stop layer that prevents the second metal layer 122 from being etched in a process of etching the seed layer.

Accordingly, the first metal layer 121 in the embodiment may include a metal material different from that of the second metal layer 122. For example, the first metal layer 121 may include a first metal material, and the second metal layer 122 may include a second metal material different from the first metal material.

Specifically, the second metal layer 122 may include copper (Cu). For example, the second metal layer 122 may also be referred to as a copper metal layer including copper. In addition, the first metal layer 121 may include a metal material different from the copper (Cu). For example, the first metal layer 121 may include at least one metal material among nickel (Ni), palladium (Pd), and gold (Au). Specifically, the first metal layer 121 may include a nickel metal layer, a palladium metal layer, and a gold metal layer disposed on the copper metal layer.

For example, a seed layer may be removed with an etchant such as sulfuric acid and hydrogen peroxide in a process of etching the seed layer used to form the first circuit pattern layer 120. Accordingly, the first metal layer 121 may include a metal material not removed by the etchant.

For example, the second metal layer 122 is disposed in a concave portion provided on an upper surface of the insulating layer 110. In this case, the second metal layer 122 is provided while filling a part of the concave portion of the insulating layer. Accordingly, a stepped portion may be provided between an upper surface of the second metal layer 122 and an upper surface of the insulating layer 110. In addition, the first metal layer 122 may be provided while filling the stepped portion.

In this case, the first metal layer 121 in the embodiment includes a plurality of metal layers. In addition, the embodiment prevents the second metal layer 122 from being oxidized while preventing the second metal layer 122 from being etched as the first metal layer 121 includes a plurality of metal layers.

Specifically, the first metal layer 121 may include a first-first metal layer 121-1, a first-second metal layer 121-2, and a first-third metal layer 121-3 (see FIG. 10).

The first-first metal layer 121-1 may mean a metal layer disposed on an outermost side of the first circuit pattern layer 120.

The first-first metal layer 121-1 may include gold (Au). For example, the first-first metal layer 121-1 may include only pure gold (Au). Alternatively, the first-first metal layer 121-1 may be formed of an alloy including gold (Au). Preferably, the first-first metal layer 121-1 may further include at least one metal selected from among silver, cobalt, palladium, copper, zinc, and an inorganic material while having gold (Au) as a main component. The first-first metal layer 121-1 may also be referred to as a gold metal layer including gold (Au) in the first circuit pattern layer 120.

The first-first metal layer 121-1 may function to prevent oxidation of the first circuit pattern layer 120. In addition, the first-first metal layer 121-1 may function to prevent the first circuit pattern layer 120 from being etched in a process of etching the seed layer. Furthermore, the first-first metal layer 121-1 may function to improve wire bonding or solder bonding in a process of mounting a chip.

The first-first metal layer 121-1 may have a thickness ranging from 0.01 μm to 0.08 μm. The first-first metal layer 121 may have a thickness ranging from 0.02 μm to 0.07 μm. The first-first metal layer 121-1 may have a thickness ranging from 0.03 μm to 0.06 μm. When the thickness of the first-first metal layer 121-1 is smaller than 0.01 μm, an etching prevention effect of the first-first metal layer 121 may be insufficient. When the thickness of the first-first metal layer 121-1 is smaller than 0.01 μm, solder joint properties or wire bonding properties may not satisfy required values. When the thickness of the first-first metal layer 121-1 exceeds 0.08 μm, a manufacturing cost of the circuit board may increase.

The first-second metal layer 121-2 may be disposed under the first-first metal layer 121-1. The first-second metal layer 121-2 may include a metal material different from that of the first-first metal layer 121-1. For example, the first-second metal layer 121-2 may include palladium (Pd). The first-second metal layer 121-2 may include pure palladium. Alternatively, the first-second metal layer 121-2 may further include at least one metal among cobalt, zinc, and an inorganic material while having palladium as a main component. The first-second metal layer 121-2 may also be referred to as a palladium metal layer including palladium in the first circuit pattern layer 120.

The first-second metal layer 121-2 may function to improve solder bonding properties. For example, the first-second metal layer 121-2 may function to improve reliability in a process reflowing of a solder. For example, the first-second metal layer 121-2 enables a reflow process of the solder at a high temperature (eg, 260° C. or more), and thus improves physical and electrical reliability of a semiconductor package.

The first-second metal layer 121-2 may have a thickness ranging from 0.01 μm to 0.08 μm. The first-second metal layer 121-2 may have a thickness ranging from 0.02 μm to 0.07 μm. The first-second metal layer 121-2 may have a thickness ranging from 0.03 μm to 0.06 μm. When the thickness of the first-second metal layer 121-2 is less than 0.01 μm, the effect of increasing the reflow process may be insufficient. When the thickness of the first-second metal layer 121-2 exceeds 0.08 μm, an overall thickness of the first circuit pattern layer 120 may increase.

The first-first metal layer 121-1 may have the same thickness as the first-second metal layer 121-2. For example, a thickness of the first-first metal layer 121-1 may satisfy a range of 0.95 to 1.05 times a thickness of the first-second metal layer 121-2. For example, a thickness of the first-first metal layer 121-1 may satisfy a range of 0.97 to 1.03 times a thickness of the first-second metal layer 121-2. For example, a thickness of the first-first metal layer 121-1 may satisfy a range of 0.98 to 1.02 times a thickness of the first-second metal layer 121-2. The first-first metal layer 121-1 may also be referred to as a nickel metal layer including nickel (Ni) in the first circuit pattern layer 120.

The first-third metal layer 121-3 may be disposed under the first-second metal layer 121-2. The first-third metal layer 121-3 may be disposed between the first-second metal layer 121-2 and the second metal layer 122. The first-third metal layer 121-3 may function to prevent copper (Cu) constituting the second metal layer 122 from diffusing into the first-first metal layer 121-1. Furthermore, the first-third metal layer 121-3 may improve bonding strength between the second metal layer 122 and the first-first metal layer 121-1 or the first-second metal layer 121-2.

The first-third metal layer 121-3 may include nickel (Ni). For example, the first-third metal layer 121-3 may include pure nickel. For example, the first-third metal layer 121-3 may be a nickel alloy layer including at least one other metal material while having nickel as a main component.

The first-third metal layer 121-3 may be formed in a thin film type or in a normal type.

When the first-third metal layer 121-3 is formed in a thin film type, a thickness of the first-third metal layer 121-3 may satisfy a range of 0.1 μm to 1.0 μm. A thickness of the first-third metal layer 121-3 may satisfy a range of 0.12 μm to 0.8 μm. A thickness of the first-third metal layer 121-3 may satisfy a range of 0.14 μm to 0.6 μm. When the thickness of the first-third metal layer 121-3 is less than 0.1 μm, the copper (Cu) diffusion preventing effect may be insufficient.

When the first-third metal layer 121-3 is formed in a normal type, a thickness of the first-third metal layer 121-3 may satisfy a range of 3 μm to 7 μm.

Accordingly, when the first-third metal layer 121-3 is formed in a thin film type, the first-third metal layer 121-3 may satisfy a range of 1.25 to 100 times a thickness of the first-first metal layer 121-1 and/or the first-second metal layer 121-2.

In addition, when the first-third metal layer 121-3 is formed in a normal shape, the first-third metal layer 121-3 may satisfy a range of 35 to 700 times a thickness of the first-first metal layer 121-1 and/or the first-second metal layer 121-2.

In the embodiment, the first-first metal layer 121-1, the first-second metal layer 121-2, and the first-third metal layer 121-3 are formed sequentially in a process of forming the first circuit pattern layer 120. Then, a second metal layer 122 is formed on the first-third metal layer 121-3. Through this, in the embodiment, it is possible to prevent the first circuit pattern layer 120 from being etched in a process of etching the seed layer, and accordingly, accordingly, a step between an upper surface of the insulating layer 110 and an upper surface of the first circuit pattern layer 120 may be removed.

Accordingly, in the embodiment, an upper surface of the insulating layer 110 and an upper surface of the first circuit pattern layer 120 may be positioned on the same plane. Preferably, an upper surface of the insulating layer 110 and an upper surface of the first-first metal layer 121-1 may be positioned on the same plane.

Therefore, the embodiment can improve the physical and electrical reliability of the first circuit pattern layer 120, thereby improving product reliability.

In addition, an inner wall of the concave portion of the insulating layer 110 may be positioned on the same plane as a side surface of the first circuit pattern layer 120. For example, side surfaces of the first-first metal layer 121-1, the first-second metal layer 121-2, the first-third metal layer 121-3, and the second metal layer 122 may be positioned on the same plane as the inner wall of the concave portion of the insulating layer 110.

Meanwhile, as described above, the first circuit pattern layer 120 includes a pad 120P and a trace 120T. In addition, the pad 120P and the trace 120T may have the same layer structure.

For example, the pad 120P includes a first metal layer 121P and a second metal layer 122P. In addition, the first metal layer 121P of the pad 120P may include a first-first metal layer 121-1P, a first-second metal layer 121-2P, and a first-third metal layer 121-3P.

For example, the trace 120T includes a first metal layer 121T and a second metal layer 122T. In addition, the first metal layer 121T of the trace 120T may include a first-first metal layer 121-1T, a first-second metal layer 121-2T, and a first-third metal layer 121-3T.

Meanwhile, the circuit board of the embodiment includes a through electrode 140.

The through electrode 140 passes through the insulating layer 110 and thus can electrically connect circuit pattern layers disposed on different layers.

For example, the through electrode 140 is disposed within the insulating layer 110. The through electrode 140 may connect a lower surface of the first circuit pattern layer 120 and an upper surface of the second circuit pattern layer 130.

The through electrode 140 may be formed by filling an inside of a through hole formed in the insulating layer 110 with a metal material.

The through hole may be formed by any one of mechanical, laser, and chemical processing. When the through hole is formed by machining, it can be formed using methods such as milling, drilling, and routing. When the through hole is formed by laser processing, it can be formed using methods such as UV or CO2 laser. When the through hole is formed by chemical processing, it can be formed using a chemical containing amino silane, ketones, or the like. Accordingly, at least one of plurality of insulating layers may be opened.

Meanwhile, the laser processing is a cutting method that concentrates optical energy on a surface to melt and evaporate a part of the material to take a desired shape, accordingly, complex formations by computer programs can be easily processed, and even composite materials that are difficult to cut by other methods can be processed.

In addition, the laser processing has a cutting diameter of at least 0.005 mm, and has the advantage of a wide range of processable thicknesses.

A laser processing drill preferably uses a YAG (Yttrium Aluminum Garnet) laser, a CO2 laser, or an ultraviolet (UV) laser. YAG laser is a laser that can process both copper foil layers and insulating layers, and CO2 laser is a laser that can process only insulating layers.

When the through hole is formed, the through electrode 140 may be formed by filling the inside of the through hole with a conductive material. The metal material forming the through electrode 140 may be any one material selected from copper (Cu), silver (Ag), tin (Sn), gold (Au), nickel (Ni), and palladium (Pd). In addition, the conductive material filling may use any one or a combination of electroless plating, electrolytic plating, screen printing, sputtering, evaporation, ink-jetting and dispensing.

Meanwhile, the circuit board of the embodiment may include a first protective layer 150 and a second protective layer 160. The first protective layer 150 and the second protective layer 160 may be respectively disposed on upper and lower surfaces of the insulating layer 110.

The first protective layer 150 may be disposed on an upper surface of the insulating layer 110. The first protective layer 150 may include an opening vertically overlapping an upper surface of the first circuit pattern layer 120.

Preferably, the first protective layer 150 may include an opening vertically overlapping the pad 120P of the first circuit pattern layer 120. In this case, a width of the opening of the first protective layer 150 may be smaller than that of the pad 120P. Accordingly, at least a portion of the upper surface of the pad 120P may be covered with the first protective layer 150.

The second protective layer 160 may be disposed under a lower surface of the insulating layer 110. The second protective layer 160 may include an opening vertically overlapping a lower surface of the second circuit pattern layer 130.

A circuit board of the embodiment includes a circuit pattern layer having an ETS structure. For example, the circuit board of the embodiment includes a first circuit pattern layer disposed on an upper surface of an insulating layer. The first circuit pattern layer means a circuit pattern layer disposed on an outermost side of the circuit board. The first circuit pattern layer includes a plurality of metal layers. The first circuit pattern layer includes a first metal layer and a second metal layer. The first metal layer may be a barrier layer that prevents the second metal layer from being etched in a process of removing a seed layer used to form the first circuit pattern layer. Accordingly, the embodiment can prevent the second metal layer from being etched when the seed layer is etched. Accordingly, the embodiment can remove a step provided between an upper surface of the first circuit pattern layer and the insulating layer, thereby improving physical and electrical reliability. Specifically, the embodiment may allow an upper surface of the first circuit pattern layer 120 and an upper surface of the insulating layer to be positioned on the same plane.

Meanwhile, the first metal layer according to the embodiment may have a multi-layer structure. The first metal layer may include a first-first metal layer, a first-second metal layer, and a first-third metal layer. The first-first metal layer may refer to a metal layer disposed at an outermost part of the first circuit pattern layer. For example, the first metal layer may include a gold metal layer, a palladium metal layer, and a nickel metal layer in order from an upper part, and the second metal layer may include a copper metal layer. In this case, an upper surface of the first-first metal layer may improve solder bonding and wire bonding properties while preventing etching and oxidation of the first circuit pattern layer. The first-second metal layer enables a solder reflow process at a high temperature, thereby improving of the second metal layer. As described above, the first metal layer of the embodiment may have a three-layer structure, and accordingly, it can improve the physical and electrical reliability of the first circuit pattern layer.

### Semiconductor Package

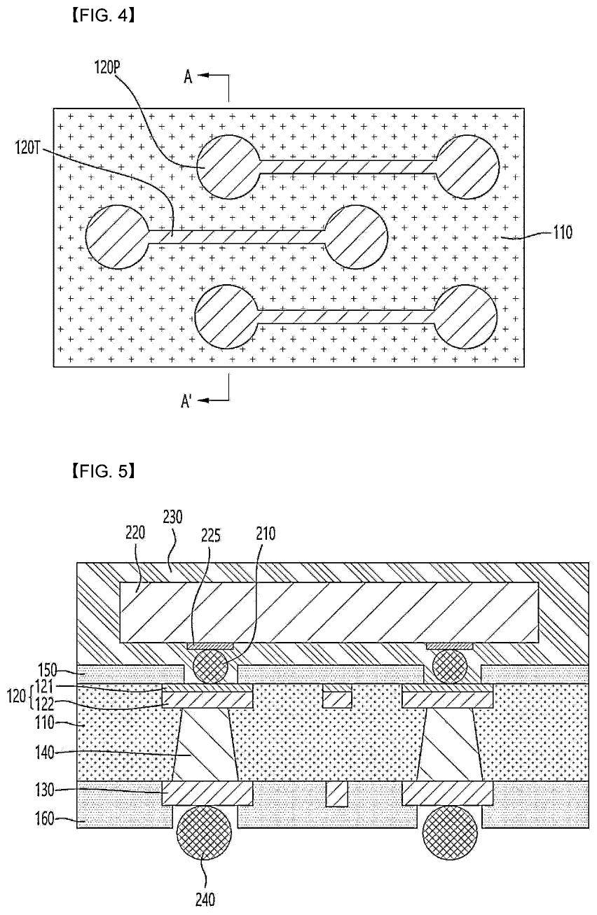

FIG. 5 is a view showing a semiconductor package according to an embodiment.

Referring to FIG. 5, a semiconductor package according to an embodiment includes a circuit board shown in FIG. 2, at least one chip mounted on the circuit board, a molding layer molding the chip, and a connection portion for coupling with the chip or an external substrate.

The semiconductor package includes a first connection portion 210 disposed on the first circuit pattern layer 120. Preferably, the first connection portion 210 may be disposed on the first metal layer 121 of the first circuit pattern layer 120. More preferably, the first connection portion 210 may be disposed on the first-first metal layer 121-1 of the first metal layer 121 of the first circuit pattern layer 120.

The first connection portion 210 may have a hexahedral shape. For example, a cross section of the first connection portion 210 may include a rectangular shape. A cross section of the first connection portion 210 may include a rectangle or a square. For example, the first connection portion 210 may have a spherical shape. For example, a cross section of the first connection portion 210 may include a circular shape or a semicircular shape. For example, a cross section of the first connection portion 210 may have a partially or entirely rounded shape. A cross sectional shape of the first connection portion 210 may be a flat surface on one side and a curved surface on the other side. The first connection portion 210 may be a solder ball, but is not limited thereto.

Meanwhile, in an embodiment, a chip 220 may be disposed on the connection portion 210. The chip 220 may be a processor chip. For example, the chip 220 may be an application processor (AP) chip among a central processor (eg, CPU), a graphic processor (eg, GPU), a digital signal processor, a cryptographic processor, a microprocessor, and a microcontroller. A terminal 225 of the chip 220 may be connected to the pad 120P of the first circuit pattern layer 120 through the first connection portion 210.

Also, although not shown in the drawing, the package substrate according to the embodiment may further include an additional chip. For example, in an embodiment, at least two chips of a central processor (eg CPU), a graphic processor (eg GPU), a digital signal processor, a cryptographic processor, a microprocessor, and a microcontroller may be disposed on the circuit board at a predetermined interval. For example, the chip 220 in the embodiment may include a central processor chip and a graphic processor chip, but is not limited thereto.

Meanwhile, the plurality of chips may be spaced apart from each other at a predetermined interval on the circuit board. For example, the predetermined interval between the plurality of chips may be 150 μm or less. For example, the predetermined interval between the plurality of chips may be 120 μm or less. For example, the predetermined interval between the plurality of chips may be 100 μm or less.

Preferably, the predetermined interval between the plurality of chips may have a range of 60 μm to 150 μm. Preferably, the predetermined interval between the plurality of chips may have a range of 70 μm to 120 μm. Preferably, the predetermined interval between the plurality of chips may have a range of 80 μm to 110 μm. When the predetermined interval between the plurality of chips is less than 60 μm, a problem may occur in operation reliability due to mutual interference between the plurality of chips. When the predetermined interval between the plurality of chips is greater than 150 μm, signal transmission loss may increase as a distance between the plurality of chips increases. When the predetermined interval between the plurality of chips is greater than 150 μm, a volume of the semiconductor package may increase.

The semiconductor package may include a molding layer 240. The molding layer 240 may be disposed while covering the chip 220. For example, the molding layer 240 may be an EMC (Epoxy Mold Compound) formed to protect the mounted chip 220, but is not limited thereto.

In this case, the molding layer 240 may have a low dielectric constant in order to increase heat dissipation properties. For example, the dielectric constant (Dk) of the molding layer 240 may be 0.2 to 10. For example, the dielectric constant (Dk) of the molding layer 240 may be 0.5 to 8. For example, the dielectric constant (Dk) of the molding layer 240 may be 0.8 to 5. Accordingly, in the embodiment, the molding layer 250 has a low dielectric constant, so that heat dissipation properties for heat generated from the chip 220 can be improved.

Meanwhile, the package substrate 200 may include the second connection portion 250 disposed on a lowermost side of the circuit board. The second connection portion 250 may be disposed on a lower surface of the second circuit pattern layer 130 exposed through the second protective layer 160.

### Manufacturing Method

Hereinafter, a method of manufacturing a circuit board according to an embodiment will be described.

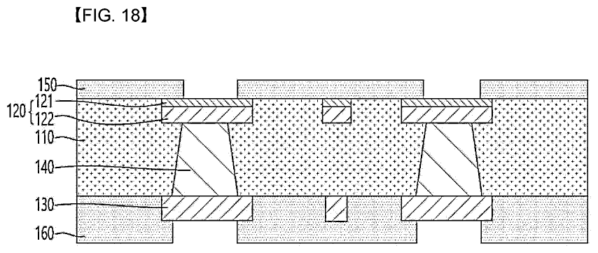

FIGS. 6 to 18 are views showing a manufacturing method of a circuit board shown in FIG. 2 in order of process.

Referring to FIG. 6, the embodiment can prepare a basic material for manufacturing a circuit board by an ETS method.

For example, the embodiment may prepare a carrier board in which a carrier insulating layer CB1 and a carrier metal layer CB2 are disposed on at least one surface of the carrier insulating layer CB1. In this case, the carrier metal layer CB2 may be disposed on only one of first and second surfaces of the carrier insulating layer CB1, or may be disposed on both sides of the carrier insulating layer CB1. For example, the carrier metal layer CB2 is disposed on only one surface of the carrier insulating layer CB1, and thus an ETS process for manufacturing the circuit board may be performed only on the one surface. Alternatively, the carrier metal layer CB2 may be disposed on both sides of the carrier insulating layer CB1, and thus the ETS process for manufacturing the circuit board may be simultaneously performed on both sides of the carrier board. In this case, it is possible to manufacture two circuit boards at once.

The carrier metal layer CB2 may be formed by performing electroless plating on the carrier insulating layer CB1. Alternatively, the carrier insulating layer CB1 and the carrier metal layer CB2 may be CCL (Copper Clad Laminate).

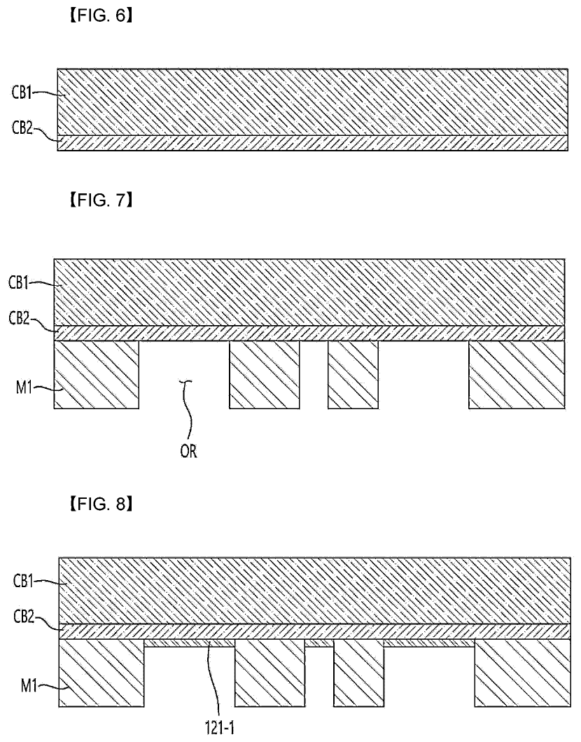

Next, referring to FIG. 7, the embodiment proceeds with a process of forming a mask M1 on the carrier metal layer CB2. In this case, the mask M1 may be disposed to entirely cover the carrier metal layer CB2. Next, in the embodiment, the formed mask M1 may be exposed and developed.

Specifically, the embodiment may proceed with a process of forming an opening OR overlapping a region of the carrier metal layer CB2 in a vertical direction where the first circuit pattern layer 120 is to be formed by exposing and developing the mask M1.

The opening OR may be formed on a surface of the carrier metal layer CB2 to correspond to a region where the first circuit pattern layer 120 is to be formed.

In this case, the embodiment may proceed with a process of curing the mask M1 having the openings OR through the exposure and development. Curing of the mask M1 may include curing using ultraviolet rays and curing using infrared rays.

For example, in the embodiment, the mask M1 may be cured using ultraviolet rays ranging from 5 mV to 100 mV. Alternatively, in the embodiment, the mask M1 may be cured by infrared heat.

As described above, in the embodiment, bonding strength between the carrier metal layer CB2 and the mask M1 may be improved by additionally performing a process of curing the mask M1. Accordingly, the first circuit pattern layer 120 formed in the opening OR may be miniaturized by improving the bonding strength between the mask M1 and the carrier metal layer CB2. For example, in the embodiment, a line width and a space of the trace of the first circuit pattern layer 120 may be reduced by additionally performing a process of curing the mask M1. Furthermore, in the embodiment, it is possible to form a space between the traces smaller than the line width of the trace of the first circuit pattern layer 120 by additionally performing a process of curing the mask M1.

Next, referring to FIG. 8, the embodiment may proceed with a process of forming the first metal layer 121 in the opening OR of the cured mask M1 using the carrier metal layer CB2 as a seed layer. Preferably, the embodiment may proceed with a process of forming a first-first metal layer 121-1 of a first metal layer 121 in the opening OR of the mask M1.

Next, referring to FIG. 9, the embodiment may proceed with a process of forming the first-second metal layer 121-2 under the first-first metal layer 121-1 in the opening OR of the cured mask M1 by using the carrier metal layer CB2 as a seed layer.

Next, referring to FIG. 10, the embodiment may proceed with a process of forming the first-third metal layer 121-3 under the first-second metal layer 121-2 in the opening OR of the cured mask M1 by using the carrier metal layer CB2 as a seed layer.

As described above, the embodiment may proceed with a process of forming the first metal layer 121 including the first-first metal layer 121-1, the first-second metal layer 121-2, and the first-third metal layer 121-3 by sequentially performing electrolytic plating on the carrier metal layer CB2 as a seed layer.

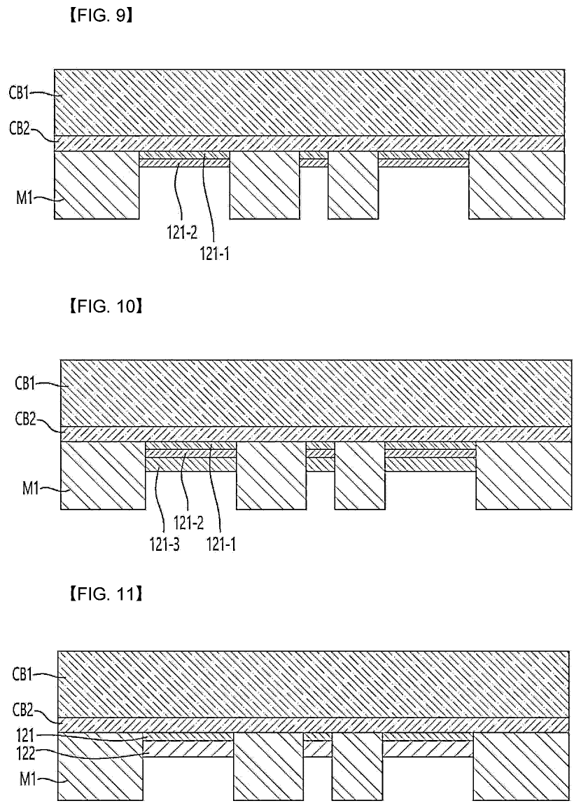

Next, referring to FIG. 11, the embodiment may proceed with a process of forming a second metal layer 122 by performing electroplating under the first metal layer 121 using the carrier metal layer CB2 as a seed layer.

Next, referring to FIG. 12, the embodiment may proceed with a process of removing the mask M1 when a process of forming the first circuit pattern layer 120 including the first metal layer 121 and the second metal layer 122 is completed.

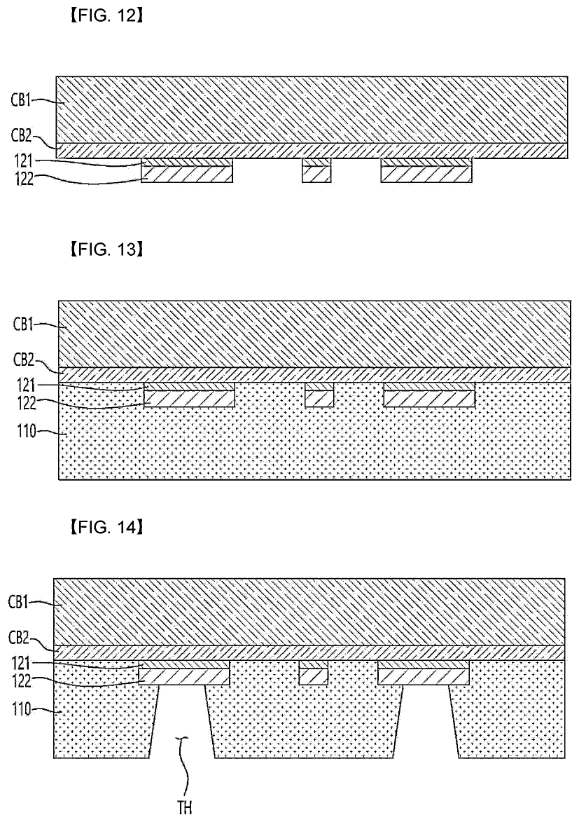

Next, as shown in FIG. 13, the embodiment may proceed with a process of forming an insulating layer 110 covering the first circuit pattern layer 120 on the carrier metal layer CB2.

Next, referring to FIG. 14, the embodiment may proceed with a process of forming a through hole TH in the insulating layer 110. The through hole TH may be formed by laser processing, but is not limited thereto.

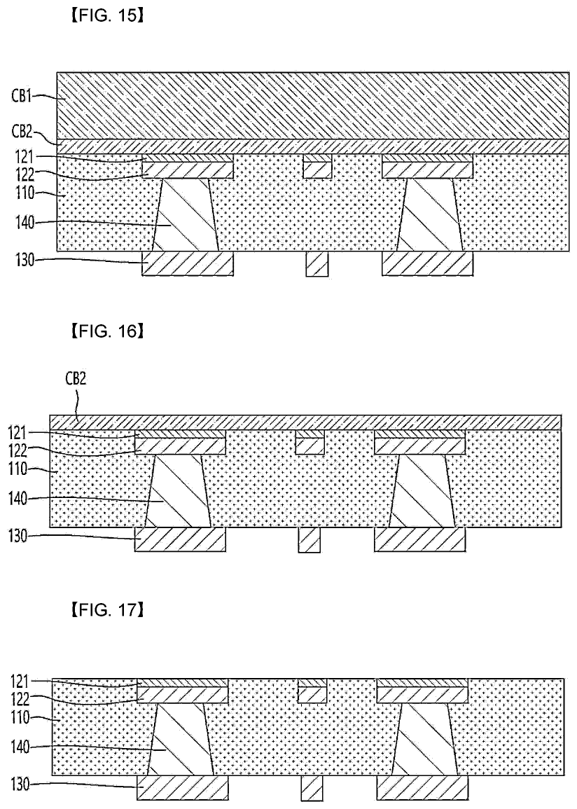

Next, referring to FIG. 15, the embodiment may proceed with a process of forming a through electrode 140 filling the through hole TH. In addition, the embodiment may proceed with a process of forming a second circuit pattern layer 130 connected to the through electrode 140 under the lower surface of the insulating layer 110 together with the through electrode 140.

Next, as shown in FIG. 16, the embodiment may proceed with a process of removing the carrier insulating layer CB1 of the carrier board on the circuit board manufactured as described above. For example, the embodiment may proceed with a process of separating the carrier insulating layer CB1 and the carrier metal layer CB2 of the carrier board.

Next, as shown in FIG. 17, the embodiment may proceed with a process of etching and removing the carrier metal layer CB2 remaining on an upper surface of the insulating layer 110 of the circuit board. Accordingly, an upper surface of the insulating layer 110 and an upper surface of the first circuit pattern layer 120 may be exposed.

In this case, the first-first metal layer 121-1 of the first circuit pattern layer 120 may include a metal material different from that of the carrier metal layer CB2. For example, the first-first metal layer 121-1 may include gold (Au), which is not etched when the carrier metal layer CB2 is etched. Accordingly, in the embodiment, when the carrier metal layer CB2 is etched, only the carrier metal layer CB2 may be removed. Accordingly, in the embodiment, the upper surface of the insulating layer 110 and the upper surface of the first circuit pattern layer 120 may be positioned on the same plane.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other. Furthermore, when the circuit board having the above-described characteristics of the invention is used in a transportation device such as a vehicle, it is possible to transmit a high-current signal required by the vehicle at a high speed, thereby improving the safety of the transportation device. Furthermore, the circuit board and the semiconductor package including the same can be operated normally even in an unexpected situation occurring in various driving environments of the transportation device, thereby safely protecting the driver.

Features, structures, effects, etc. described in the above embodiments are included in at least one embodiment, and it is not necessarily limited to only one embodiment. Furthermore, features, structures, effects, etc. illustrated in each embodiment can be combined or modified for other embodiments by those of ordinary skill in the art to which the embodiments belong. Accordingly, the contents related to such combinations and variations should be interpreted as being included in the scope of the embodiments.

In the above, the embodiment has been mainly described, but this is only an example and does not limit the embodiment, and those of ordinary skill in the art to which the embodiment pertains will appreciate that various modifications and applications not illustrated above are possible without departing from the essential characteristics of the present embodiment. For example, each component specifically shown in the embodiment can be implemented by modification. And the differences related to these modifications and applications should be interpreted as being included in the scope of the embodiments set forth in the appended claims

1.-10. (canceled)

11. A circuit board comprising:
an insulating layer having a concave portion at an upper surface thereof;
a protective layer disposed on the insulating layer; and
a first circuit pattern layer disposed between the insulating layer and the protective layer and disposed in the concave portion.
wherein the protective layer includes an opening passing through an upper surface of the protective layer and a lower surface of the protective layer,
wherein the first circuit pattern layer includes a pad portion overlapping the opening along a vertical direction; and a trace portion covered with the protective layer without overlapping the opening along the vertical direction,
wherein the pad portion and the trace portion include a plurality of metal layers identical to each other, and
wherein each of the pad portion and the trace portion includes:
a first metal layer disposed on a lower surface of the concave portion; and
a second metal layer disposed on the first metal layer to fill a stepped portion between an upper surface of the first metal layer and an upper surface of the insulating layer.

12. The circuit board of claim 11, wherein a width of the opening of the protective layer is smaller than a width of the second metal layer of the pad portion, and
at least a portion of an upper surface of the second metal layer of the pad portion is covered with the protective layer.

13. The circuit board of claim 11, wherein the first metal layer and the second metal layer include different metal materials.

14. The circuit board of claim 11, wherein side surfaces of the first and second metal layers are disposed on the same plane as an inner wall of the concave portion.

15. The circuit board of claim 14, wherein the upper surface of the first metal layer is positioned lower than the upper surface of the insulating layer, and
wherein an upper surface of the second metal layer is positioned on the same plane as the upper surface of the insulating layer.

16. The circuit board of claim 13, wherein the first metal layer includes copper, and the second metal layer includes a metal material other than copper.

17. The circuit board of claim 16, wherein the second metal layer is provided with a plurality of layers including different metal materials.

18. The circuit board of claim 17, wherein the second metal layer includes:
a first layer disposed on the first metal layer;
a second layer disposed on the first layer; and
a third layer disposed on the second layer.

19. The circuit board of claim 18, wherein the first layer of the second metal layer includes nickel,
the second layer of the second metal layer includes palladium, and
the third layer of the second metal layer includes gold.

20. The circuit board of claim 11, wherein the insulating layer is provided with a plurality of layers stacked along the vertical direction, and
the concave portion is provided on an upper surface of an insulating layer disposed on an uppermost side among the plurality of layers.

21. The circuit board of claim 18, wherein a width of the first metal layer is same as a width of the second metal layer.

22. The circuit board of claim 21, wherein a side surface of the first metal layer and a side surface of the second metal layer are entirely covered with the insulating layer.

23. The circuit board of claim 18, wherein a thickness of the first layer of the second metal layer has a range of 0.1 μm to 1.0 μm,
wherein a thickness of the second layer of the second metal layer has a range of 0.01 μm to 0.08 μm, and
wherein a thickness of the third layer of the second metal layer has a range of 0.01 μm to 0.08 μm.

24. The circuit board of claim 18, wherein a thickness of the first layer of the second metal layer has a range of 3.0 μm to 7.0 μm,
wherein a thickness of the second layer of the second metal layer has a range of 0.01 μm to 0.08 μm, and
wherein a thickness of the third layer of the second metal layer has a range of 0.01 μm to 0.08 μm.

25. The circuit board of claim 18, wherein a thickness of the third layer of the second metal layer ranges from 0.95 times to 1.05 times the thickness of the second layer of the second metal layer, and
wherein a thickness of the first layer of the second metal layer ranges from 1.25 times to 100 times a thickness of any one of a thickness of the second layer of the second metal layer and a thickness of the third layer of the second metal layer.

26. The circuit board of claim 18, wherein a thickness of the third layer of the second metal layer ranges from 0.95 times to 1.05 times a thickness of the second layer of the second metal layer, and
wherein a thickness of the first layer of the second metal layer ranges from 35 times to 700 times a thickness of any one of a thickness of the second layer of the second metal layer and a thickness of the third layer of the second metal layer.

27. The circuit board of claim 11, further comprising:
a second circuit pattern layer disposed under a lower surface of the insulating layer,
wherein a number of metal layers of the second circuit pattern layer is smaller than a number of metal layers of the first circuit pattern layer.

28. The circuit board of claim 18, wherein the first circuit pattern layer includes a pad and a trace, and
wherein each of the pad and the trace includes the first metal layer, the first layer of the second metal layer, the second layer of the second metal layer, and the third layer of the second metal layer.

29. A semiconductor package comprising:
an insulating layer having a concave portion on an upper surface thereof;
a protective layer disposed on the insulating layer;
a circuit pattern layer disposed between the insulating layer and the protective layer and disposed in the concave portion;
a connection part disposed in the opening of the protective layer; and
a chip disposed on the connection part,
wherein the protective layer includes an opening passing through an upper surface of the protective layer and a lower surface of the protective layer,
wherein the first circuit pattern layer includes a pad portion overlapping the opening along a vertical direction; and a trace portion covered with the protective layer without overlapping the opening along the vertical direction,
wherein the pad portion and the trace portion include a plurality of metal layers identical to each other, and
wherein each of the pad portion and the trace portion includes:
a first metal layer disposed on a lower surface of the concave portion; and
a second metal layer disposed on the first metal layer to fill a stepped portion between an upper surface of the first metal layer and an upper surface of the insulating layer.

30. The semiconductor package of claim 29, wherein the chip includes first and second chips spaced apart in a vertical or horizontal direction,
wherein the first chip includes a central processor (CPU), and
wherein the second chip includes a graphics processor (GPU).
